(19) United States
(12) Patent Application Publication
(10) Pub. No.: US 2002/0190353 A1
(43) Pub. Date: Dec. 19, 2002

(54) Plastic package structure for communication component

(76) Inventors: Jyh-Sheng Pan, Hsinchu Hsien (TW); Kuo-Ching Liu, Hsinchu City (TW); Yu-Tai Chen, Taipei (TW); Li-Wei Chen, Hsinchu (TW); Fu-Chun Huang, Hsinchu City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/883,288

(22) Filed: Jun. 19, 2001

(51) Int. Cl. H05K 5/06; H01L 23/495; H01L 23/48

(52) U.S. Cl. 257/666; 257/692; 257/787

(57) ABSTRACT

The present invention provides a plastic package structure for a communication component. The plastic package structure comprises a leadframe and a die. Two sides of a die pad of the leadframe have two protruding portions. The die is glued on the protruding portions of the die pad to form a hollow region between the die and the die pad. After the operation of soldering, an insulating seal is used to seal the other two sides of the die and the die pad to form a closed cavity on the circuit face of the die. An encapsulation is then used to sheathe all the above parts. Thereby, a plastic package for a communication component provided by the present invention has low cost and high production speed, and is suitable to mass production.

### FIELD OF THE INVENTION

The present invention relates to an improved package structure of plastic package technology for an electronic component. And particularly to a plastic package structure for a communication component so that the circuit region of a die thereof has a closed cavity isolated from exterior, thereby securing normal operation of the circuit.

### BACKGROUND OF THE INVENTION

Along with continual development of the electronic industry, the range of applications of plastic package which have low costs and can be mass-produced becomes wider and wider. Plastic package predominates the package of electronic components in the prior art. As shown in FIG. 1, a metal leadframe or a printed circuit board is used as a package substrate. A die is disposed at a specific position thereon. Thin gold wires are then soldered to connect bonding pads of the die to pins of the leadframe or the substrate for connection. An encapsulation is then used to sheathe the die and the gold wires to exactly protect the poor circuit structure. Finally, the outer leads of the leadframe of the substrate are used to connect the circuit of the die to other devices. This kind of electronic package using a leadframe or a printed circuit board as a substrate is easy to mass-produce, and has a low cost.

However, the design of some circuits, it is not allowable to let any material on the surface of certain circuits. Therefore, the above package structure cannot apply to the package of many electronic components such as communication components because covering material will cause original designed electronic signals to be transmitted abnormally. Ceramic packages are mainly used for this kind of components. As shown in FIG. 2, a ceramic package structure uses multiple layers ceramic plates to form a ceramic substrate 10 having a cavity 12 at the center thereof. A die 14 is disposed in the cavity 12, and a cover plate 16 is used to cover thereon. This kind of electronic package using the ceramic substrate 10 has better reliability. Ceramic package needs the ceramic substrate 10 of multiple layers ceramic plates. However, it is not easy to process ceramic material, and the processing cost is high. Additionally, a special die bonder is required for the operation of die bonding due to limit of the structure of the ceramic substrate 10, the throughput is far lower than that of the common plastic package. Moreover, aluminum wires are generally used for wire bonding, and the wire bonding speed of aluminum wires is only half of the gold wires. Therefore, it is not easy to mass-produce the ceramic package, and the cost is high.

Replacing ceramic packages with the above has become the trend in the future. For instance, in U.S. Pat. No. 5,892,417, a hollow adhesive tape is used to glue a leadframe and a die together, with a closed space formed at the center thereof, and subsequent package steps are then performed. The locating accuracy of the adhesive tape needs to be higher because the adhesive tape is pasted at four sides of the leadframe, and the size of the die is larger because the bond pad is situated outside the adhesive tape, hence detrimental to the whole process and the cost. Moreover, the original process cannot be followed, resulting in much inconvenience. Accordingly, the present invention uses adhesive tapes and the flip chip technology to improve the plastic package structure, thereby reducing the die size and providing a package structure of low cost and fast production.

### SUMMARY OF THE INVENTION

The primary object of the present invention is to improve the structure of a prior art plastic package so that a closed cavity can be formed on specific circuits of a die in the encapsulation, and molding compound and other materials are not allowed to enter the cavity to affect the I/O of signals of component, thereby providing a plastic package structure suitable for a communication component.

Another object of the present invention is to provide a plastic package structure capable of exploiting the mature process and the present equipment to package communication components so as to achieve lower the cost, increase the production, and accomplish mass production.

Yet another object of the present invention is to reduce the die size to minimum in the plastic package structure for reducing the cost.

To achieve the above objects, a plastic package structure for a communication component comprises a leadframe with a die pad at the center thereof. A die is bonded on the die pad using adhesive tapes, with the contact portions being at two opposite sides of the die and the edge of the die pad. Wires are then used to connect the die to leads of the leadframe. Next, an insulating seal is used to seal the other two sides of the die and the die pad by means of dispenser to form a closed cavity. The outer layer is an encapsulation sheathing the die pad, the die, the wires, and part of the leads to protect them from damages due to external forces.

The various objects and advantages of the present invention will be more readily understood from the following detailed description when read in conjunction with the appended drawings, in which:

### BRIEF DESCRIPTION OF THE DRAWINGS

FIG. 1 is a diagram of a prior art plastic package;

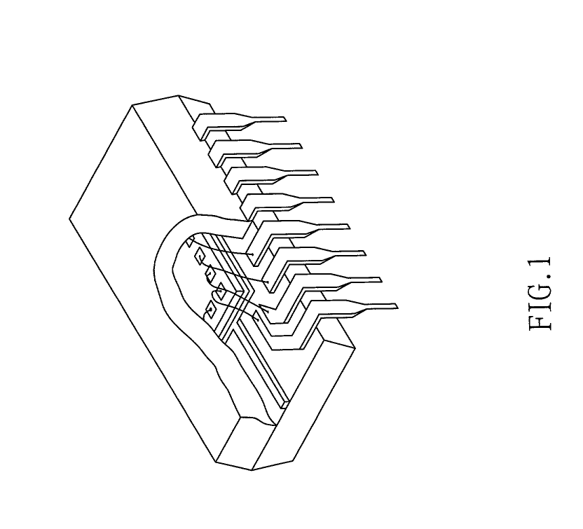

FIG. 2 is a structure diagram of a prior art ceramic package;

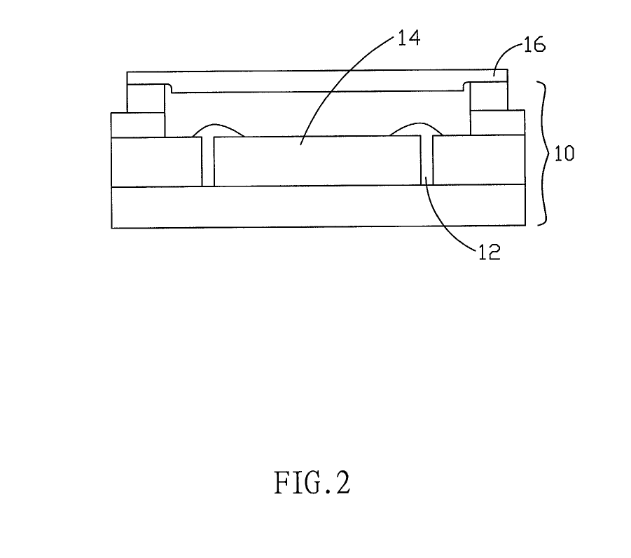

FIG. 3 shows a perspective view of one embodiment of the present invention and cross-sectional views along lines A-A′ and B-B′ in the perspective view;

FIG. 4 shows a perspective view of another embodiment of the present invention having a recessed die pad and cross-sectional views along lines C-C′ and D-D′ in the perspective view; and

FIG. 5 shows a perspective view of yet another embodiment of the present invention having an transferring substrate and cross-sectional views along lines E-E′ and F-F′ in the perspective view.

### DETAILED DESCRIPTION OF THE PREFERRED EMBODIMENTS

The present invention is characterized mainly in that a leadframe is used as a support to carry a die, and the protruding portions and the dispensing technology are exploited to form a closed cavity between the die and the leadframe to be used as a protection shield for the transmission of signals of a communication component.

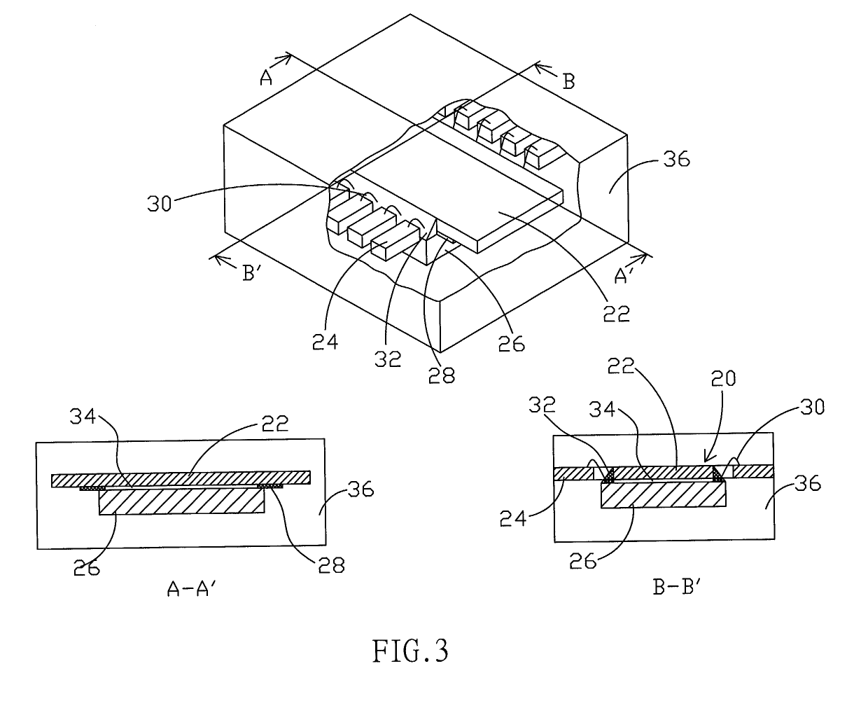

As shown in FIG. 3, a plastic package structure for a communication component comprises a leadframe 20 having a die pad 22 at the center and a plurality of leads at the periphery thereof. The leadframe 20 is made of metal package material. One surface of a die 26 is a circuit face. Two separating sheets 28, generally being adhesive tapes, are used to glue the die 26 on the surface of the die pad 22. Two opposite sides of the die 26 are glued to two edges of the die pad 22 so that the two separating sheets 28 can be used as protruding portions of the die pad 22. Thereby, a hollow region will be formed between the die pad 22 and the die 26, and the circuit face of the die 26 will face the die pad 22. A wire-bonding machine is then used to connect a plurality of wires to I/O pads on the die 26 and the leads 24, thereby connecting the circuit in the die 26 to the leads 24. The wires 30 used are gold wires or aluminum wires.

After the operation of wire bonder, an insulating seal 32 is used to seal the other two sides not pasted by the separating sheets 28 between the die 26 and the die pad 22 to form a protection shield for preventing external materials from entering. Thereby, a closed cavity 34 will be formed between the circuit face of the die 26 and the die pad 22 to prevent encapsulation 36 from covering the circuit face of the die 26 during mold pressing process, thereby protecting the circuit face of the die. The circuit face is the action region of the communication component. The insulating seal 32 is placed at two sides of the die to provide a special buffering effect. That is, it can absorb electric noise generated during the operation of the communication component, thereby enhancing the function and characteristic of the communication component.

The encapsulation 36 at the outmost layer is formed by means of mold press or flip chip using thermosetting molding compound, commonly being epoxy resin, to sheathe the die pad 22, the die 26, the adhesive taps 28, the wires 30, the insulating seal 32, and part of the leads 24 to provide protection, preventing the die from damages due to factors such as impact, dust, or moisture. The part of the leads 24 protruding out of the encapsulation 36 are used as outer leads to provide electric connection to other devices.

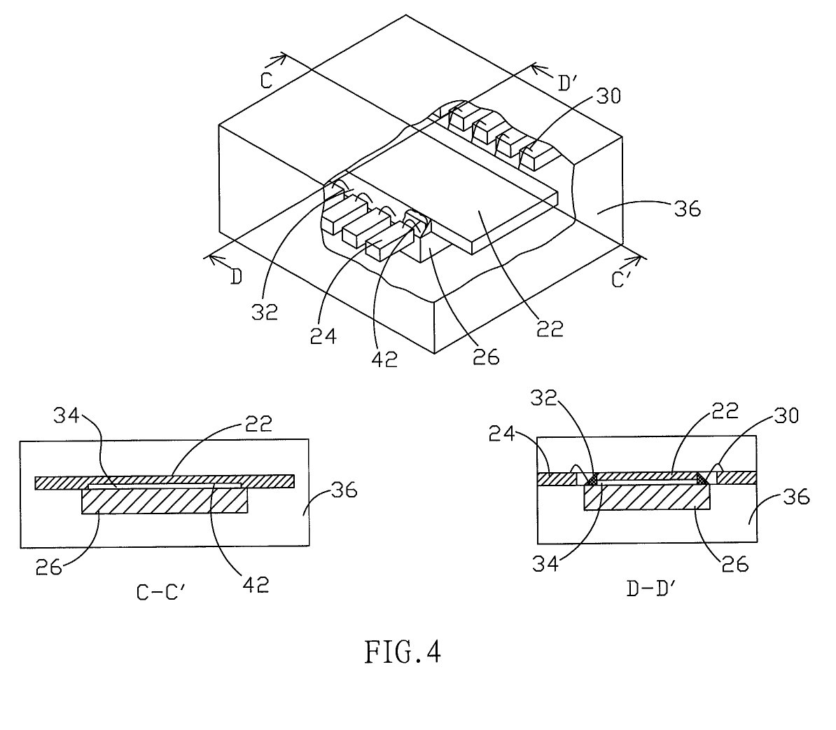

As shown in FIG. 4, a recess 42 can be formed at the center of the above die pad 22 so that two side walls of the recess 42 are used as two protruding portions, of which the portion glued with the die 26 is only the edge of the die pad 22. In this way, a closed cavity 34 can also be formed.

The present invention improves the original structure of a prior art plastic package to form a closed cavity on specific circuits of a die in the encapsulation, thereby preventing molding compound or other materials from entering to affect signals of the communication component. Moreover, the present invention only uses two adhesive tapes pasted at two sides of the die, the requirement of positioning accuracy of the adhesive tapes is lower. Moreover, the mature process and equipment in existent package plants can be followed to package communication components, hence simultaneously lowering the cost, increasing the production, and facilitating mass production.

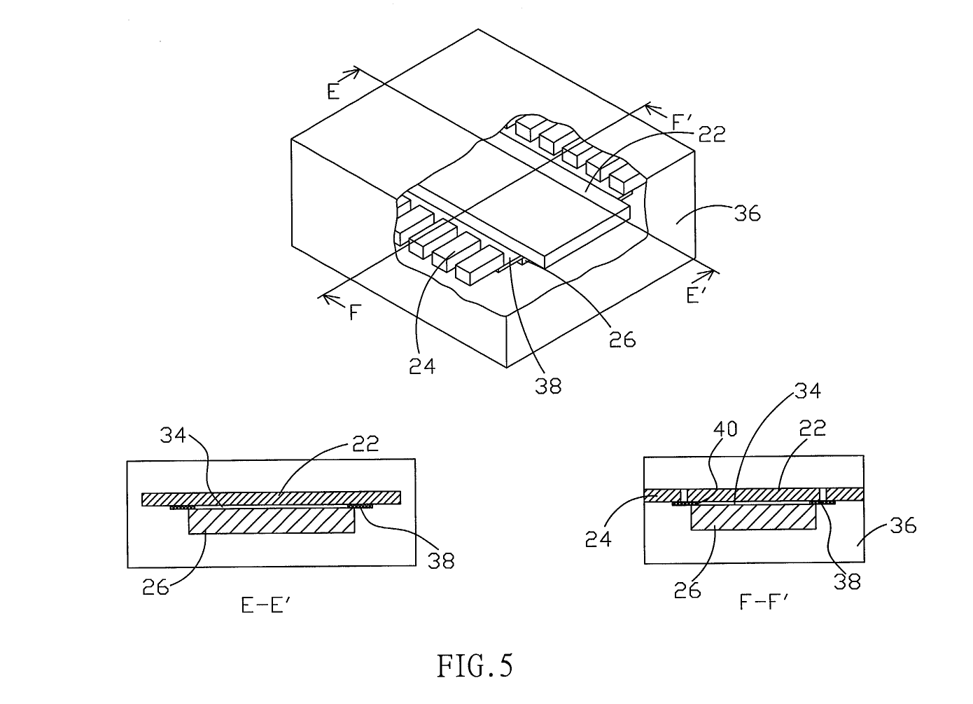

The above embodiment uses a package structure having a leadframe to illustrate the teachings of the present invention. The present invention can also use other means to form a closed cavity. As shown in FIG. 5, the die pad 22 on the leadframe 20 can be directly disposed on a transferring substrate 38, and internal interconnects of the transferring substrate 38 are also connected to the leads 24. The substrate 38 is generally a printed circuit board. A slot 40 is formed at the center of the surface of the transferring substrate 38 so that the slot 40 forms a closed cavity 34 when the circuit face of the die 26 faces the slot 40 and is mounted on the transferring substrate 38. The die 26 is electrically connected to the transferring substrate 38. An encapsulation 36 is used to sheathe all the above parts to let part of the leads 24 protrude out of the encapsulation and be used as outer leads. A plurality of wires can be used to achieve electric connection between the die and the transferring substrate.

Therefore, for communication components, the present invention replaces prior art ceramic substrates with low-cost leadframe or substrate, thereby effectively lowering the cost, increasing the production speed, and facilitating mass production.

Although the present invention has been described with reference to the preferred embodiments thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. A plastic package structure for a communication component, comprising:
a leadframe having a die pad and a plurality of leads at the periphery thereof;
at least a die whose front face of circuit region glued on said die pad;
a plurality of wires connecting said die with said leads by means of wire bonding; and
an encapsulation sheathing said die pad, said die, said wires, and part of said leads, part of said leads protruding out of said encapsulation being used as outer leads;
said plastic package structure being characterized in that two opposite sides of the surface of said die pad have two protruding portions to let the front face of circuit region of said die face said die pad and be mounted on said protruding portions, an insulating seal is used to seal the other two sides of said die and said die pad to form a closed cavity between said die and said die pad by means of dispensing, and said encapsulation also sheathes said protruding portions and said insulating seal.

2. The plastic package structure as claimed in claim 1, wherein each opposite side of said die pad has a separating sheet to be used as said protruding portion.

3. The plastic package structure as claimed in claim 2, wherein said separating sheet is an adhesive tape.

4. The plastic package structure as claimed in claim 1, wherein the surface of said die pad of said leadframe has a recess disposed at the center thereof so that two sides of said recess can be used as said protruding portions.

5. The plastic package structure as claimed in claim 1, wherein said leadframe is made of metal material.

6. The plastic package structure as claimed in claim 1, wherein said wires are either gold wires or aluminum wires.

7. The plastic package structure as claimed in claim 1, wherein said encapsulation is formed by means of mold press or dispenser.

8. The plastic package structure as claimed in claim 1, wherein said insulating seal and said encapsulation are made of thermosetting material.

9. A plastic package structure for a communication component, comprising:
a leadframe having a die pad and a plurality of leads at the periphery thereof;
a transferring substrate situated on said die pad and having a slot disposed at the center thereof, interconnects in said transferring substrate being connected to said leads;
at least a die mounted on said transferring substrate and covering said slot to form a closed cavity, said die being electrically connected to said transferring substrate; and
an encapsulation sheathing said die pad, said transferring substrate, said die, and part of said leads, part of said leads protruding out of said encapsulation being used as outer leads.

10. The plastic package structure as claimed in claim 9, wherein a plurality of wires can be used to electrically connect said transferring substrate to said die.

11. The plastic package structure as claimed in claim 9, wherein said leadframe is made of metal material.

12. The plastic package structure as claimed in claim 9, wherein said wires are either gold wires or aluminum wires.

13. The plastic package structure as claimed in claim 9, wherein said encapsulation is formed by means of mold press or dispenser.

14. The plastic package structure as claimed in claim 9, wherein said encapsulation is made of thermosetting material.
